(19) United States
(12) Patent Application Publication
(10) Pub. No.: US 2025/0190341 A1
(43) Pub. Date: Jun. 12, 2025

(54) OPERATION METHOD OF MEMORY DEVICE, OPERATION METHOD OF CONTROLLER CONFIGURED TO CONTROL MEMORY DEVICE, AND OPERATION METHOD OF STORAGE DEVICE INCLUDING MEMORY DEVICE AND CONTROLLER

(71) Applicant: Samsung Electronics Co., Ltd., Suwon-si (KR)

(72) Inventors: Eyikwon HWANG, Suwon-si (KR); JANGKWON LEE, Suwon-si (KR); SUNG-HWAN BAE, Suwon-si (KR); SEUNGHYUN SHIN, Suwon-si (KR)

(21) Appl. No.: 18/773,721

(22) Filed: Jul. 16, 2024

(30) Foreign Application Priority Data
Dec. 12, 2023 (KR) 10-2023-0179844

(51) Int. Cl. G06F 12/02; G06F 11/10

(52) U.S. Cl. CPC G06F 12/0246; G06F 11/1004

(57) ABSTRACT

A method of operating a memory device including a memory cell array and a memory circuit includes receiving a first command from a controller, determining, in response to the first command, whether first device information stored in the memory circuit has an error, receiving, in response to the determining that the first device information has the error, a reset command from the controller, and performing a refresh operation on the memory circuit in response to the reset command. The first device information includes information about an operation parameter and an operating frequency of the memory device.

### CROSS-REFERENCE TO RELATED APPLICATIONS

This application claims priority under 35 U.S.C. § 119 to Korean Patent Application No. 10-2023-0179844 filed on Dec. 12, 2023, in the Korean Intellectual Property Office, the disclosures of which are incorporated by reference herein in their entireties.

### BACKGROUND

Embodiments of the present disclosure described herein relate to a semiconductor memory, and more particularly, relate to an operation method of a memory device, an operation method of a controller configured to control the memory device, and an operation method of a storage device including the memory device and the controller.

A semiconductor memory is classified as a volatile memory, which loses data stored therein when a power is turned off, such as a static random access memory (SRAM) and a dynamic random access memory (DRAM) or a nonvolatile memory, which retains data stored therein even when a power is turned off, such as a flash memory, a phase-change RAM (PRAM), a magnetic RAM (MRAM), a resistive RAM (RRAM), and a ferroelectric RAM (FRAM).

A flash memory is being widely used as a high-capacity storage medium. The flash memory operates based on various operation information or device information. In this case, the operation information or device information is stored in a memory circuit included in the flash memory. Nowadays, as the degree of integration of the flash memory is improved, the size of the memory circuit included in the flash memory is decreasing. As the size of the memory circuit decreases, various errors occur in data stored in the memory circuit. Accordingly, correcting of an error of data stored in the memory circuit is desirable.

### SUMMARY

Embodiments of the present disclosure provide an operation method of a memory device with improved reliability and improved performance, an operation method of a controller configured to control the memory device, and an operation method of a storage device including the memory device and the controller.

According to an aspect of the present disclosure, a method of operating a memory device including a memory cell array and a memory circuit includes receiving a first command from a controller, determining, in response to the first command, whether first device information stored in the memory circuit has an error, receiving, in response to the determining that the first device information has the error, a reset command from the controller, and performing a refresh operation on the memory circuit in response to the reset command. The first device information includes information about an operation parameter and an operating frequency of the memory device.

According to an aspect of the present disclosure, a method of operating a controller to control a memory device includes transmitting a first command to the memory device, transmitting a status read command to the memory device, receiving status information from the memory device, determining whether an error is present in device information stored in a memory circuit included in the memory device based on the status information, and transmitting, in response to determining that the error is present in the device information, a reset command for refreshing the memory circuit to the memory device. The device information includes information about an operation parameter and an operating frequency of the memory device.

According to an aspect of the present disclosure, a method of operating a storage device which includes a memory device and a controller includes transmitting, by the controller, a first command to the memory device, performing, by the memory device, a cyclic redundancy check (CRC)-check operation on device information stored in a memory circuit of the memory device in response to the first command, receiving, by the controller, a result of the CRC-check operation from the memory device, transmitting, by the controller, a reset command to the memory device in response to the result of the CRC-check operation indicating that an error is present in the device information, and performing, by the memory device, a refresh operation on the memory device in response to the reset command. The device information includes information about an operation parameter and an operating frequency of the memory device.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a storage device according to an embodiment of the present disclosure.

FIG. 2 is a block diagram illustrating a memory device of FIG. 1.

FIG. 3 is a flowchart illustrating an operation of a memory device of FIG. 2.

FIG. 4 is a flowchart illustrating operation S160 (i.e., an operation of refreshing a memory circuit) of FIG. 3.

FIG. 5 is a flowchart illustrating an operation of a memory device of FIG. 2.

FIG. 6 is a flowchart illustrating an operation of a storage system of FIG. 1.

FIG. 7 is a flowchart illustrating an operation of a storage device of FIG. 1.

FIG. 8A is a diagram for describing device information stored in a memory circuit of FIG. 1.

FIG. 8B is a flowchart illustrating an operation of a storage device of FIG. 1.

FIG. 9 is a flowchart illustrating an operation of a storage device of FIG. 1.

FIG. 10 is a block diagram illustrating a storage device according to an embodiment of the present disclosure.

FIG. 11 is a block diagram illustrating a memory device of FIG. 10.

FIG. 12 is a flowchart illustrating an operation of a storage device of FIG. 10.

FIG. 13 is a flowchart illustrating an operation of a storage device of FIG. 10.

FIG. 14 is a flowchart illustrating an operation of a storage device of FIG. 10.

FIG. 15 is a view for describing a memory device according to an embodiment of the present disclosure.

FIG. 16 is a block diagram illustrating a host-storage system according to an embodiment of the present disclosure.

### DETAILED DESCRIPTION

Below, embodiments of the present disclosure will be described in detail and clearly to such an extent that an ordinary one in the art easily carries out the present disclosure.

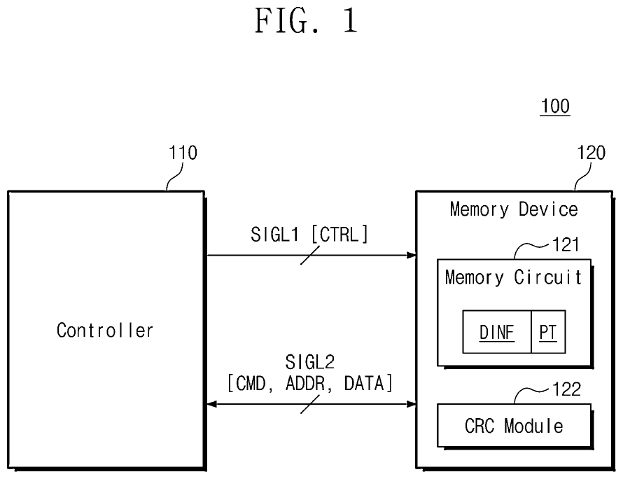

FIG. 1 is a block diagram illustrating a storage device according to an embodiment of the present disclosure. Referring to FIG. 1, a storage device 100 may include a controller 110 and a memory device 120. In an embodiment, the storage device 100 may be a high-capacity storage medium such as a solid state drive (SSD), a memory card, and a universal flash storage (UFS). In an embodiment, the storage device 100 may be included in one of information processing devices, which are configured to process a variety of information and to store the processed information, such as a personal computer (PC), a laptop, a server, a workstation, a smartphone, a tablet PC, a digital camera, and a black box. However, the present disclosure is not limited thereto. For example, the storage device 100 may be implemented in various forms and may be included in various devices or various systems.

The controller 110 may be configured to control the memory device 120. For example, under the control of an external host, the controller 110 may store data in the memory device 120 or may read data stored in the memory device 120. In an embodiment, regardless of the control of the external host, the controller 110 may perform various maintenance operations for improving the performance or reliability of the memory device 120.

In an embodiment, the controller 110 may be configured to communicate with the external host based on a given host interface. The given host interface may include at least one of various host interfaces such as a universal serial bus (USB) interface, a multimedia card (MMC) interface, a peripheral component interconnection (PCI) interface, a PCI-express (PCI-e) interface, an advanced technology attachment (ATA) interface, a serial-ATA (SATA) interface, a parallel-ATA (PATA) interface, a small computer small interface (SCSI) interface, an enhanced small disk interface (ESDI), an integrated drive electronics (IDE) interface, a mobile industry processor interface (MIPI), a nonvolatile memory-express (NVM-e) interface, and a compute express link (CXL) interface.

In an embodiment, the controller 110 may be configured to communicate with the memory device 120 through a given memory interface. The given memory interface may include at least one of various flash memory interfaces such as a toggle NAND interface (i.e., Toggle) and an open NAND flash interface (ONFI). For example, the controller 110 may transmit a control signal CTRL to the memory device 120 through first signal lines SIGL1. Through second signal lines SIGL2, the controller 110 may transmit a command CMD and an address ADDR to the memory device 120 or may exchange data DATA with the memory device 120.

The memory device 120 may operate under the control of the controller 110. For example, the memory device 120, controlled by the controller 110, may store data or may output the stored data. In an embodiment, the memory device 120 may be a NAND flash memory, but the present disclosure is not limited thereto.

In an embodiment, the memory device 120 may include a memory circuit 121 and a cyclic redundancy check (CRC) module 122 (i.e., a CRC circuit). The memory circuit 121 may be configured to store a variety of information related to the operation of the memory device 120. For example, the memory circuit 121 may store device information DINF. The memory device 120 may perform various erases (e.g., a read operation, a program operation, and an erase operation of the NAND flash memory) based on the device information DINF stored in the memory circuit 121.

In an embodiment, the device information DINF may include information about various operation parameters of the memory device 120, such as a read voltage level, a program voltage level, and an erase voltage level. In an embodiment, the device information DINF may include a variety of information of the memory device 120, such as an operating characteristic of the memory device 120, a storage capacity, and an operating frequency. In an embodiment, the device information DINF may include a variety of information of the memory device 120, such as a vender identifier, a device model, and an operating characteristic supported by a device. However, the present disclosure is not limited thereto. For example, the device information DINF may include a variety of other information related to the operation of the memory device 120.

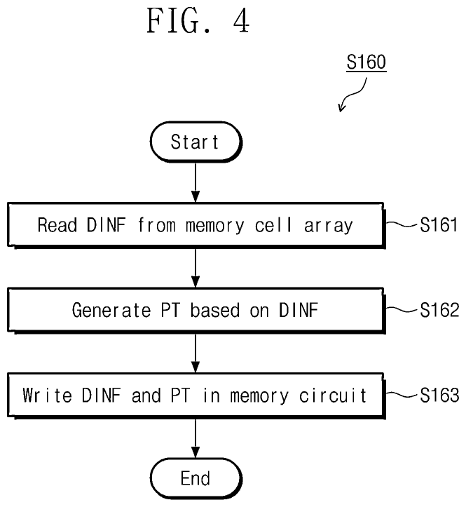

In an embodiment, the memory circuit 121 may include a plurality of latch circuits. The plurality of latch circuits may be configured to store the device information DINF based on the E-fuse manner. For example, the memory circuit 121 may include a plurality of latch circuits and a plurality of programmable electrical fuses. A value of each of the latch circuits may be determined by programming a corresponding one of the plurality of programmable electrical fuses. The device information DINF stored in the plurality of latch circuits may include an error caused by various factors. For example, neutrons may be introduced into the memory device 120 or the memory circuit 121 due to various environments, thereby causing the bit flip in the plurality of latch circuits of the memory circuit 121. The bit flip causes an error of the device information DINF stored in the memory circuit 121. This error is called a soft error. In an embodiment, because the soft error is not a hardware defect, when a refresh or e-fuse refresh operation on the memory circuit 121 is performed, the soft error may be cured. The refresh operation on the memory circuit 121 will be described in detail with reference to FIG. 4.

The CRC module 122 may be configured to generate a parity PT of the device information DINF to be stored in the memory circuit 121 and to detect a defect or an error of the device information DINF obtained from the memory circuit 121. For example, the CRC module 122 may be configured to generate the parity PT of the device information DINF. The device information DINF and the parity PT may be stored in the memory circuit 121. The CRC module 122 may detect an error based on the device information DINF and the parity PT stored in the memory circuit 121. In one embodiment, the parity PT may be a checksum used for the CRC algorithm.

In an embodiment, when an error of the device information DINF is detected by the CRC module 122, the memory device 120 may perform a refresh operation on the device information DINF stored in the memory circuit 121. In an embodiment, the error detection operation for the memory circuit 121 and the refresh operation for the memory circuit 121 may be performed under the control of the controller 110. The above operation of the storage device 100 will be described in detail with reference to the following drawings. In an embodiment, the controller 110 and the memory device 120 may be implemented as separate semiconductor chips or may be integrated into a single semiconductor chip. In an embodiment, the controller 110 and the memory device 120 that are implemented as separate chips may be separately packaged. In an embodiment, the controller 110 and the memory device 120 that are implemented as separate chips may be packaged together. For example, the controller 110 and the memory device 120 may be placed on the same plane in a package or the controller 110 and the memory device 120 may be stacked on each other in the package.

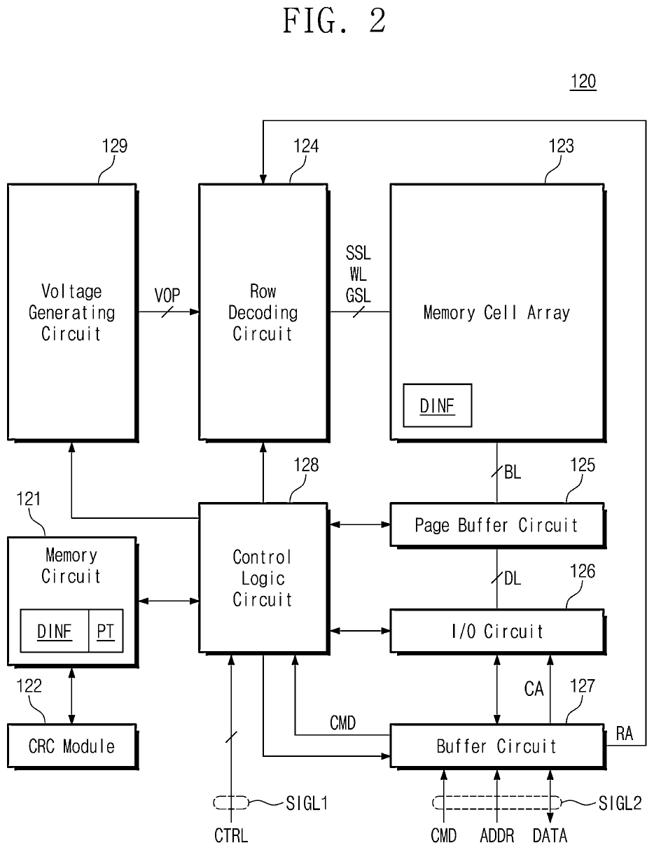

FIG. 2 is a block diagram illustrating a memory device of FIG. 1. Referring to FIGS. 1 and 2, the memory device 120 may include the memory circuit 121, the CRC module 122, a memory cell array 123, a row decoding circuit 124, a page buffer circuit 125, a data input/output circuit 126, a buffer circuit 127, a control logic circuit 128, and a voltage generating circuit 129.

The memory circuit 121 may store the device information DINF and the CRC parity PT. In an embodiment, the memory circuit 121 may include the plurality of latch circuits configured to store the device information DINF and the CRC parity PT.

The CRC module 122 may generate the CRC parity PT associated with the device information DINF. The CRC module 122 may detect an error of the device information DINF based on the device information DINF and the CRC parity PT.

The memory cell array 123 may include a plurality of memory blocks. Each of the plurality of memory blocks may include a plurality of cell strings. Each of the plurality of cell strings may include a plurality of cell transistors stacked in a direction perpendicular to a substrate. The plurality of cell transistors may be connected in series between a bit line BL and a common source line. The plurality of cell transistors may be connected to string selection lines SSL, word lines WL, and ground selection lines GSL.

In an embodiment, each of the plurality of memory blocks may be a unit of the erase operation. Memory cells included in the same memory block among the plurality of memory blocks may be erased at the same time. In an embodiment, each of the plurality of memory blocks may be divided into sub-blocks. Each of the plurality of sub-blocks may correspond to a unit of the erase operation. Memory cells included in the same sub-block among the plurality of sub-blocks may be erased at the same time.

In an embodiment, the memory cell array 123 may store the device information DINF. In an embodiment, the device information DINF may be stored in a meta region of the memory cell array 123. In an embodiment, the meta region of the memory cell array 123 may correspond to at least one memory block, which may be referred to a meta block. The meta region may include some of the plurality of memory blocks of the memory cell array 123. The meta region may store a variety of information (e.g., the device information DINF and mapping information) related to the operation of the memory device 120 or the storage device 100. In the initialization operation of the memory device 120, the device information DINF stored in the memory cell array 123 may be written in the memory circuit 121. In the operation of the memory device 120, the control logic circuit 128 may control various components of the memory device 120 based on the device information DINF stored in the memory circuit 121.

The row decoding circuit 124 may be connected to the memory cell array 123 through the string selection lines SSL, the word lines WL, and the ground selection lines GSL. The row decoding circuit 124 may operate under the control of the control logic circuit 128. For example, the row decoding circuit 124, controlled by the control logic circuit 128, may decode a row address RA received from the buffer circuit 127, and based on the decoding result of the row address RA, the row decoding circuit 124 may control or drive the string selection lines SSL, the word lines WL, and the ground selection lines GSL or may control voltages applied to the string selection lines SSL, the word lines WL, and the ground selection lines GSL.

The page buffer circuit 125 may be connected to the memory cell array 123 through the bit lines BL. The page buffer circuit 125 may be connected to the data input/output circuit 126 through a plurality of data lines DL. The page buffer circuit 125 may operate under the control of the control logic circuit 128. For example, in the program operation of the memory device 120, the page buffer circuit 125 may store data to be programmed in the memory cell array 123 under the control of the control logic circuit 128. In the read operation of the memory device 120, the page buffer circuit 125 may sense voltages of the bit lines BL and may store the sensed voltages as read data.

The data input/output circuit 126 may be connected to the page buffer circuit 125 through the plurality of data lines DL. The data input/output circuit 126 may receive a column address CA from the page buffer circuit 125. The data input/output circuit 126 may transfer the read data stored in the page buffer circuit 125 to the buffer circuit 127 depending on the column Address CA. The data input/output circuit 126 may transfer data received from the buffer circuit 127 to the page buffer circuit 125 based on the column address CA.

The buffer circuit 127 may receive the command CMD and the address ADDR through the second signal lines SIGL2 from the controller 110 and may exchange the data DATA with an external device (e.g., the controller 110) through the second signal lines SIGL2. In an embodiment, the second signal lines SIGL2 may be data signal lines (e.g., DQ lines).

The buffer circuit 127 may operate under the control of the control logic circuit 128. The buffer circuit 127 may transfer the command CMD to the control logic circuit 128. The buffer circuit 127 may transfer the row address RA of the address ADDR to the row decoding circuit 124 and may transfer the column address CA of the address ADDR to the data input/output circuit 126. The buffer circuit 127 may exchange the data DATA with the data input/output circuit 126.

The control logic circuit 128 may exchange the control signal CTRL with the external device (e.g., the controller 110) through the first signal lines SIGL1. The control logic circuit 128 may control the buffer circuit 127 based on the control signals CTRL such that the buffer circuit 127 routes the command CMD, the address ADDR, and the data DATA. The control logic circuit 128 may decode the command CMD received from the buffer circuit 127 and may control the memory device 120 or various components of the memory device 120 based on the decoding result of the command CMD.

Under the control of the control logic circuit 128, the voltage generating circuit 129 may generate various operating voltages VOP which are used in the memory device 120. In an embodiment, the operating voltages VOP may include program voltages, pass voltages, selection read voltages, non-selection read voltages, erase voltages, or verify voltages.

As described above, according to an embodiment of the present disclosure, the memory device 120 may perform various operations (e.g., a read operation, a program operation, and an erase operation) based on the device information DINF stored in the memory circuit 121. In this case, the memory device 120 may detect an error of the device information DINF by performing a CRC-check operation on the device information DINF stored in the memory circuit 121. When an error of the device information DINF is detected, the memory device 120 may perform the refresh operation on the memory circuit 121.

In this case, the memory circuit 121 may be prevented from being unnecessarily refreshed. For example, when an input/output exception (e.g., a read fail, a program fail, or an erase fail) occurs in a conventional memory device, the conventional memory device performs the refresh operation on the memory circuit 121 regardless of whether an error is present in the device information DINF. In contrast, according to an embodiment of the present disclosure, refreshing the memory circuit 121 may be performed only when detecting an error in the device information DINF, and thus, the memory circuit 121 may be prevented from being unnecessarily refreshed. Such reduction of unnecessary refresh operation may enhance the performance of the memory device 120 or the storage device 100.

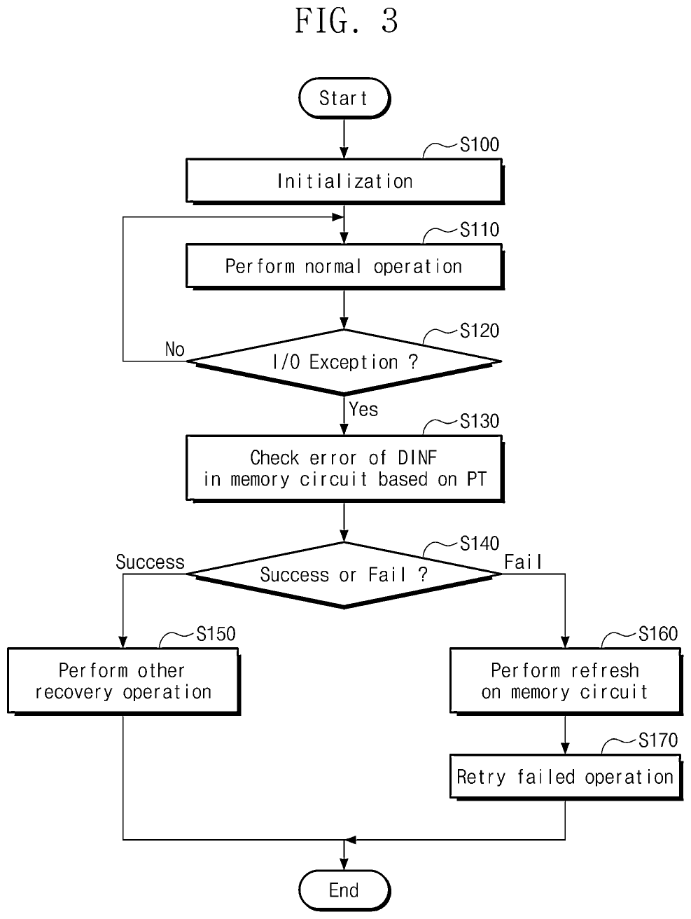

FIG. 3 is a flowchart illustrating an operation of a memory device of FIG. 2. Referring to FIGS. 2 and 3, in operation S100, the memory device 120 may perform the initialization operation. For example, the memory device 120 may perform the initialization operation under the control of the controller 110. In an embodiment, in the initialization operation, the memory device 120 may read the device information DINF stored in the memory cell array 123, may generate the parity PT of the device information DINF, and may store the device information DINF and the parity PT in the memory circuit 121.

In operation S110, the memory device 120 may perform the normal operation of the NAND flash memory, for example. For example, the memory device 120 may perform the read operation, the program operation, or the erase operation under the control of the controller 110. In an embodiment, the memory device 120 may perform the normal operation of the NAND flash memory, for example, by using the device information DINF stored in the memory circuit 121.

In operation S120, the memory device 120 may determine whether an input/output exception occurs. For example, the read fail, the program fail, or the erase fail may occur while the memory device 120 performs the normal operation of the NAND flash memory, for example. In this case, the memory device 120 may determine that the input/output exception occurs. That is, the input/output exception may indicate a situation where the memory device 120 does not operate normally. When the input/output exception does not occur, the memory device 120 may continuously perform operation S110.

When the input/output exception occurs, in operation S130, the memory device 120 may check an error of the device information DINF stored in the memory circuit 121, based on the parity PT. For example, in the initialization operation, the device information DINF and the parity PT may be stored in the memory circuit 121. The CRC module 122 of the memory device 120 may determine whether an error occurs, by performing the CRC-check operation on the device information DINF stored in the memory circuit 121 based on the parity PT stored in the memory circuit 121.

In operation S140, the memory device 120 may determine whether the CRC-check operation succeeds or fails. That the CRC-check operation succeeds means that an error is absent from the device information DINF stored in the memory circuit 121. In this case, in operation S150, the memory device 120 may perform any other recovery operation for resolving the input/output exception.

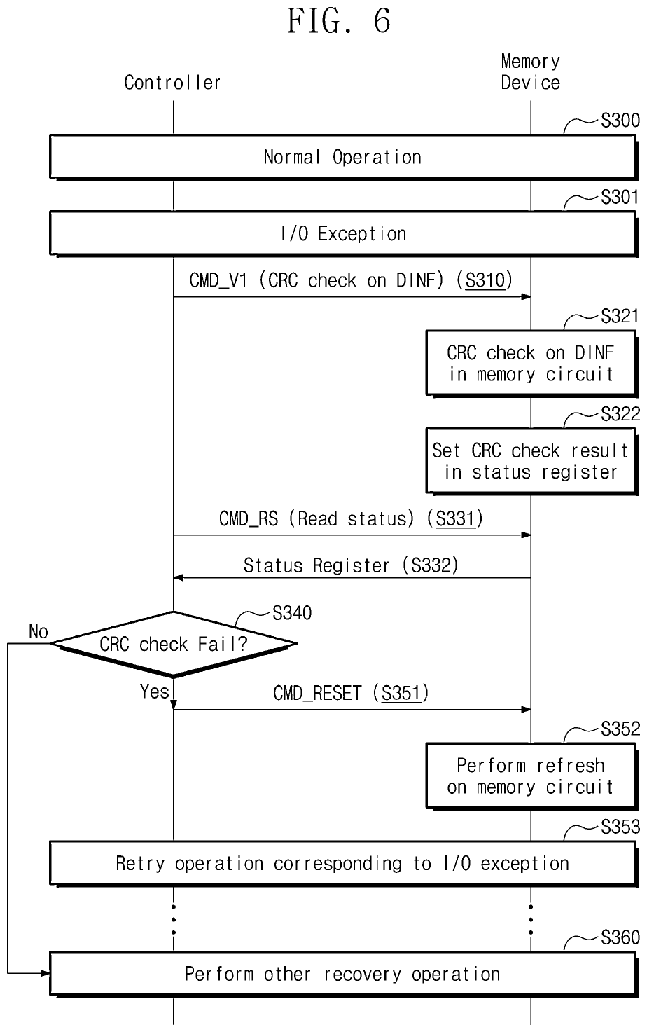

That the CRC-check operation fails means that an error is present in the device information DINF stored in the memory circuit 121. In this case, in operation S160, the memory device 120 may perform the refresh operation on the memory circuit 121. In an embodiment, the memory device 120 may read the device information DINF stored in the memory cell array 123, may generate the parity PT of the device information DINF, and may again store the device information DINF and the parity PT in the memory circuit 121. That is, as the original device information DINF stored in the memory cell array 123 is again written in the memory circuit 121, the normal device information DINF (i.e., the error-free device information DINF) may be restored in the memory circuit 121. For example, the refresh operation may be performed after the detection of the failure in the CRC-check operation, and may include reading the device information DINF from the memory cell array 123, generating the parity PT of the device information DINF read from the memory cell array 123, and storing the device information DINF and the parity PT in the memory circuit 121. The present disclosure is not limited thereto. For example, the refresh operation may be performed in the absence of any input/output exception, which will be described with reference to FIG. 6. The device information DINF and the parity PT stored in the memory circuit 121 may be referred to as first device information and first parity. The original device information DINF stored in the memory cell array 123 may be referred to as second device information, and a parity generated from the second device information may be referred to as second parity. The refresh operation may store the second device information and the second parity as the first device information and the first parity, respectively.

In operation S170, the memory device 120 may retry the failed normal operation which causes the input/output exception. The input/output exception may be caused by the error of the device information DINF. According to the above description, after the memory circuit 121 is refreshed, the same operation may be normally completed only if the input/output exception occurs due to the error of the device information DINF.

As described above, according to an embodiment of the present disclosure, when the input/output exception occurs, the memory device 120 may check whether an error is present in the device information DINF stored in the memory circuit 121. Only when an error is present in the device information DINF, because the memory circuit 121 is refreshed, the memory circuit 121 may be prevented from being unnecessarily refreshed. Accordingly, the performance of the memory device 120 may be improved. For example, refreshing the memory circuit 121 only when an error is detected in the device information DINF may prevent unnecessary refresh operations, thereby enhancing the performance of the memory device 120.

FIG. 4 is a flowchart illustrating operation S160 (i.e., an operation of refreshing a memory circuit) of FIG. 3. Referring to FIGS. 2, 3, and 4, the memory device 120 may perform the refresh operation on the memory circuit 121 through operation S161 to operation S163.

In operation S161, the memory device 120 may read the device information DINF stored in the memory cell array 123. In an embodiment, a partial region of the memory cell array 123 may be used to store a variety of information related to the operation of the memory device 120. The device information DINF may be stored in the partial region of the memory cell array 123 described above. In an embodiment, the device information DINF may be stored in the memory cell array 123 in the process of manufacturing or testing the memory device 120. In operation S162, the memory device 120 may generate the parity PT, based on the device information DINF. For example, the CRC module 122 of the memory device 120 may generate the parity PT of the device information DINF. In operation S163, the memory device 120 may write the device information DINF and the parity PT in the memory circuit 121. The device information DINF obtained from the memory cell array 123 and the normal parity PT may be stored in the memory circuit 121 through the above operations.

In an embodiment, the above refresh operation may be performed on the memory circuit 121 in the initialization operation of the memory device 120. In an embodiment, as described above, when a CRC-check result indicates that the CRC-check operation fails (i.e., when an error is detected from the device information DINF), the above refresh operation may be performed on the memory circuit 121. In an embodiment, the memory circuit 121 may be refreshed through an information block data read reset (IDR) operation.

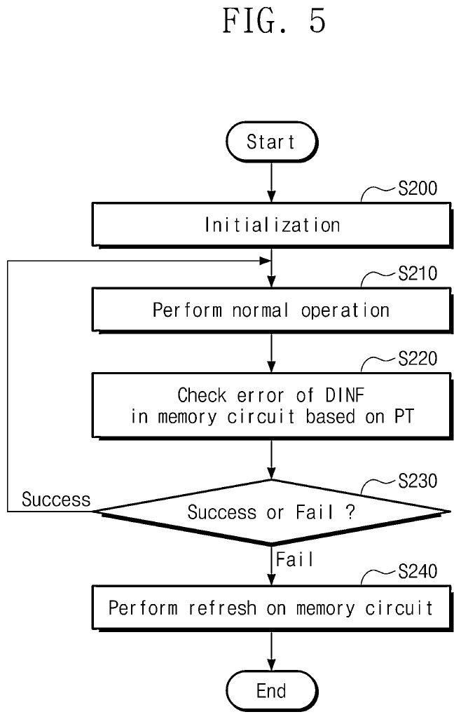

FIG. 5 is a flowchart illustrating an operation of a memory device of FIG. 2. Referring to FIGS. 2 and 5, the memory device 120 may perform operation S200 (e.g., the initialization operation) and operation S210 (e.g., the normal operation of the NAND flash memory, for example). Operation S200 and operation S210 are similar to operation S100 and operation S110 of FIG. 3, and thus, additional description will be omitted to avoid redundancy.

In operation S220, the memory device 120 may check an error of the device information DINF stored in the memory circuit 121, based on the parity PT. In an embodiment, operation S220 is similar to operation S130 of FIG. 3 except that operation S220 is performed in the absence of any input/output exception, and thus, additional description will be omitted to avoid redundancy.

In operation S230, the memory device 120 may determine whether the CRC-check operation succeeds or fails. That the CRC-check operation succeeds means that an error is absent from the device information DINF stored in the memory circuit 121. In this case, the memory device 120 may continue operation S110 without an additional operation.

That the CRC-check operation fails means that an error is present in the device information DINF stored in the memory circuit 121. In this case, in operation S240, the memory device 120 may perform the refresh operation on the memory circuit 121. Operation S240 is similar to operation S160 described with reference to FIGS. 3 and 4, and thus, additional description will be omitted to avoid redundancy.

As described above, the memory device 120 may periodically or non-periodically perform the CRC-check operation on the device information DINF stored in the memory circuit 121 and may perform the refresh operation on the memory circuit 121 depending on a result of the CRC-check operation. Accordingly, as the refresh operation on the memory circuit 121 is performed before the input/output exception of the memory device 120 is caused, the reliability of the device information DINF stored in the memory circuit 121 may be enhanced.

FIG. 6 is a flowchart illustrating an operation of a storage system of FIG. 1. According to the embodiments described with reference to FIGS. 3 to 5, the memory device 120 detects an error of the device information DINF stored in the memory circuit 121 and performs the refresh operation on the memory circuit 121 in response to the detection of an error in the device information DINF. However, the present disclosure is not limited thereto. For example, the memory device 120 may perform the above operation under the control of the controller 110.

Referring to FIGS. 1, 2, and 6, in operation S300, the controller 110 and the memory device 120 may perform the normal operation of the NAND flash memory, for example. For example, the memory device 120 may perform the read operation, the program operation, or the erase operation under the control of the controller 110.

In operation S301, an input/output exception may occur. For example, the read fail, the program fail, or the erase fail may occur while the memory device 120 is operating. The controller 110 may detect the input/output exception (e.g., a program fail or an erase fail) caused in the memory device 120 through a status read operation on the memory device 120. In an embodiment, the controller 110 may detect the input/output exception (e.g., a read fail) caused in the memory device 120 in the process of performing error correction for data read from the memory device 120.

In operation S310, the controller 110 may transmit a first command CMD_V1 to the memory device 120. For example, when the controller 110 detects the input/output exception of the memory device 120, the controller 110 may transmit the first command CMD_V1 to the memory device 120. In an embodiment, the first command CMD_V1 may be a command for the CRC-check operation on the memory circuit 121. For example, the memory device 120 may initiate the CRC-check operation upon the receipt of the first command CMD_V1. In an embodiment, the first command CMD_V1 may be implemented with a reserved command defined in the memory interface protocol between the controller 110 and the memory device 120 to support a specific operation, a vendor command, a combination of at least two operation commands defined in the memory interface protocol. In an embodiment, the memory interface protocol may include Toggle or ONFI.

In operation S321, the memory device 120 may perform the CRC-check operation on the device information DINF stored in the memory circuit 121 in response to the first command CMD_V1. For example, the memory circuit 121 may store the device information DINF and the parity PT. The CRC module 122 of the memory device 120 may determine whether an error is present in the device information DINF, based on the parity PT.

In operation S322, the memory device 120 may set or may store a CRC-check result in a status register within the memory device 120. In an embodiment, the CRC-check result may be set or may be stored at a given location of the memory device 120.

In operation S331, the controller 110 may transmit a status read command CMD_RS to the memory device 120. For example, while the memory device 120 performs operation S321 and operation S322, a ready/busy signal of the memory device 120 may be in a busy state; after operation S322 is completed, the ready/busy signal may transition to a ready state. The controller 110 may transmit the status read command CMD_RS to the memory device 120 in response to the ready/busy signal transitioning to the ready state.

In operation S332, the memory device 120 may transmit a value or status information of the status register to the controller 110. For example, the memory device 120, in response to the status read command CMD_RS, may transmit the value or status information of the status register to the controller 110. In an embodiment, the value or status information of the status register transmitted in operation S332 may include information about the CRC-check result. In an embodiment, the information about the CRC-check result may be transmitted through a given data line.

In operation S340, the controller 110 may determine whether the CRC-check operation fails, based on the value or status information of the status register. When the CRC-check operation is determined as a fail, in operation S351, the controller 110 may transmit a reset command CMD_RESET to the memory device 120.

In operation S352, the memory device 120 may perform the refresh operation on the memory circuit 121 in response to the reset command CMD_RESET. The refresh operation of the memory circuit 121 is described with reference to FIG. 4, and thus, additional description will be omitted to avoid redundancy.

In operation S353, the controller 110 and the memory device 120 may retry an operation to complete an operation which causes an input/output exception. For example, after the memory circuit 121 is completely refreshed, the controller 110 may transmit an operation command for performing the operation corresponding to the input/output exception to the memory device 120, and the memory device 120 may perform the operation corresponding to the operation command.

When the CRC-check result indicates a success in operation S340, the procedure proceeds to operation S360. In operation S360, the controller 110 and the memory device 120 may perform any other recovery operation after the input/output exception is determined not being caused by the device information DINF stored in the memory circuit 121. For example, it is assumed that the input/output exception is a read fail. In this case, after the controller 110 adjusts read voltages to be used in the memory device 120 or performs a valley search operation, the controller 110 may retry the read operation on the memory device 120. For example, it is assumed that the input/output exception is a program fail. In this case, the controller 110 may process or manage a program-failed memory block as a bad block and may migrate valid data of the failed memory block to any other normal memory block. The above recovery operations are provided only as an example, and the present disclosure is not limited thereto.

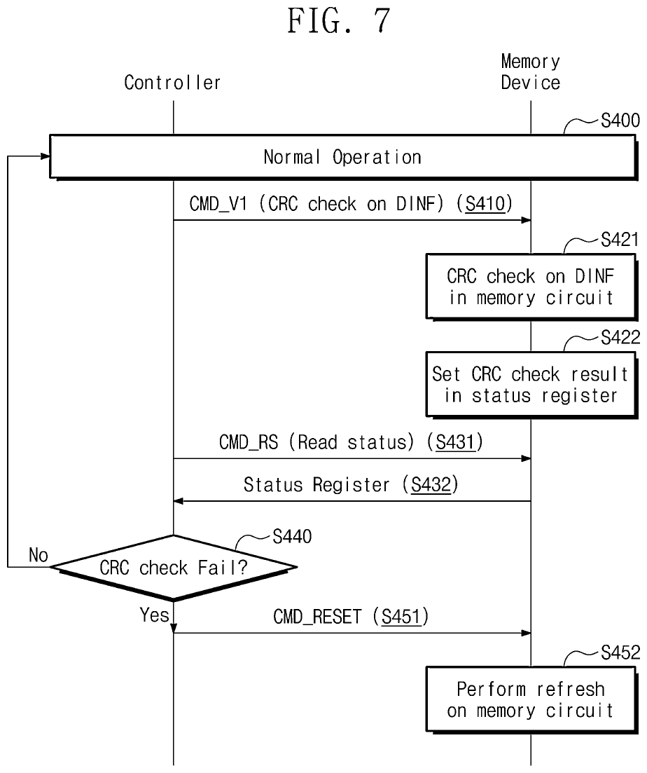

FIG. 7 is a flowchart illustrating an operation of a storage device of FIG. 1. Referring to FIGS. 1, 2, and 7, in operation S400, the controller 110 and the memory device 120 may perform the normal operation of the NAND flash memory, for example. Operation S400 is similar to operation S300 of FIG. 6, and thus, additional description will be omitted to avoid redundancy.

In operation S410, the controller 110 may transmit the first command CMD_V1 to the memory device 120. For example, the first command CMD_V1 may be a command for the CRC-check operation on the memory circuit 121 of the memory device 120. In an embodiment, the first command CMD_V1 may be implemented with a reserved command for a specific operation defined in an memory interface protocol between the memory device 120 and the controller 110, a vendor command, or a combination of at least two operation commands defined in the memory interface protocol.

The controller 110 and memory device 120 may perform operation S421, operation S422, operation S431, operation S432, operation S440, operation S451, and operation S452. Operation S421, operation S422, operation S431, operation S432, operation S440, operation S451, and operation S452 are similar to operation S321, operation S322, operation S331, operation S332, operation S340, operation S351, and operation S352 of FIG. 6, and thus, additional description will be omitted to avoid redundancy.

Unlike the embodiment of FIG. 6, in the embodiment of FIG. 7, the controller 110 may periodically or non-periodically transmit the first command CMD_V1 to the memory device 120, regardless of the occurrence of the input/output exception. In an embodiment, during an idle time of the memory device 120, the controller 110 may transmit the first command CMD_V1 to the memory device 120. In an embodiment, whenever an operation count or the number of program/erase cycles of the memory device 120 reaches a reference value, the controller 110 may transmit the first command CMD_V1 to the memory device 120. In an embodiment, whenever a driving time of the memory device 120 reaches a reference time, the controller 110 may transmit the first command CMD_V1 to the memory device 120. In an embodiment, the driving time may indicate a time period from a power-on of the memory device 120 to a current time. In an embodiment, the controller 110 may check or manage the driving time of the memory device 120 using a clock signal or a timer.

That is, even though the input/output exception does not occur in the memory device 120, the controller 110 may periodically or non-periodically determine whether an error occurs in the memory circuit 121 of the memory device 120. In this case, the reliability of the device information DINF stored in the memory circuit 121 may be improved. Accordingly, the memory circuit 121 is prevented from being unnecessarily refreshed, thereby enhancing the performance of the memory device 120 or the storage device 100.

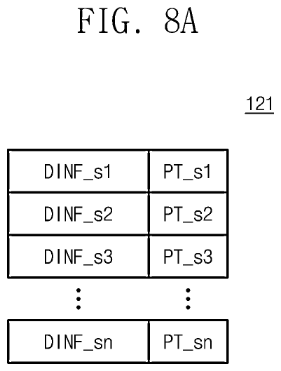

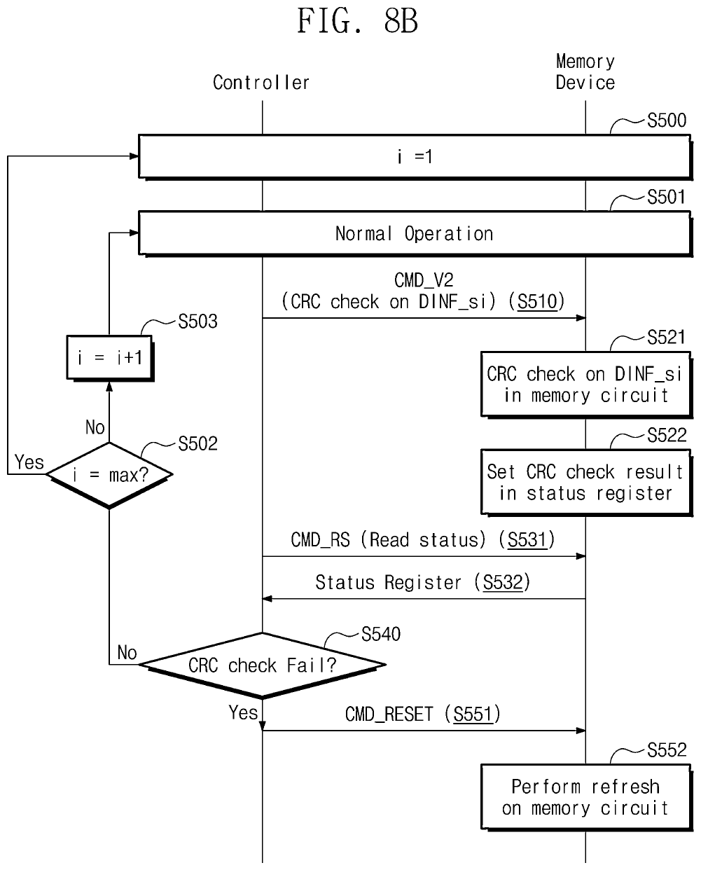

FIG. 8A is a diagram for describing device information stored in a memory circuit of FIG. 1. FIG. 8B is a flowchart illustrating an operation of a storage device of FIG. 1. First, referring to FIGS. 1, 2, and 8A, the memory circuit 121 may store the device information DINF and the parity PT. As illustrated in FIG. 8A, the device information DINF may be divided into a plurality of sub-information DINF_s1 to DINF_sn. The plurality of sub-information DINF_s1 to DINF_sn may be classified based on the CRC unit which is used by the CRC module 122.

The CRC module 122 may generate a plurality of sub-parities PT_s1 to PT_sn corresponding to the plurality of sub-information DINF_s1 to DINF_sn, respectively. The plurality of sub-information DINF_s1 to DINF_sn and the plurality of sub-parities PT_s1 to PT_sn may be stored in the memory circuit 121.

Next, referring to FIGS. 1, 2, 8A, and 8B, in operation S500, a variable “i” is set to “1”. In an embodiment, the variable “i” represents a number of an iteration in an embodiment of the present disclosure, and the present disclosure is not limited thereto.

In operation S501, the controller 110 and the memory device 120 may perform the normal operation of the NAND flash memory, for example. Operation S501 is similar to operation S300 of FIG. 6, and thus, additional description will be omitted to avoid redundancy.

In operation S510, the controller 110 may transmit a second command CMD_V2 to the memory device 120. In an embodiment, the second command CMD_V2 may be a command for the CRC-check operation on the i-th sub-information DINF_s1. In an embodiment, the second command CMD_V2 may be implemented with a reserved command for a specific operation defined in a memory interface protocol between the controller 110 and the memory device 120, a vendor command, or a combination of at least two operation commands defined in the memory interface protocol. In an embodiment, the second command CMD_V2 may include information about a location of the memory circuit 121, at which the i-th sub-information DINF_s1 is stored, or an identifier indicating the i-th sub-information DINF_s1.

In operation S521, the memory device 120 may perform the CRC-check operation on the i-th sub-information DINF_s1 stored in the memory circuit 121. In operation S522, the memory device 120 may set a CRC-check result in the status register. In an embodiment, operation S521 and operation S522 may be performed in response to the second command CMD_V2.

In operation S531, the controller 110 may transmit the status read commands CMD_RS to the memory device 120. In operation S532, the memory device 120 may transmit a value of the status register to the controller 110 in response to the status read commands CMD_RS.

In an embodiment, operation S510, operation S521, operation S522, operation S531, and operation S532 are similar to operation S410, operation S421, operation S422, operation S431, and operation S432 of FIG. 7 except that the CRC-check operation on the i-th sub-information DINF_s1 is performed, and thus, additional description will be omitted to avoid redundancy.

In operation S540, the controller 110 may determine whether the CRC-check operation fails, based on the values of the status register. When a CRC-check result indicates that the CRC-check operation does not fail, in operation S502, whether the variable “i” is a maximum value is determined. When the variable “i” is the maximum value, in operation S500, the variable “i” is again set to “1”. When the variable “i” is not the maximum value, in operation S503, the variable “i” may increase as much as “1”, and the controller 110 and the memory device 120 performs operation S501.

When the CRC-check operation fails, in operation S551, the controller 110 may transmit the reset command CMD_RESET to the memory device 120. In operation S552, the memory device 120 may perform the refresh operation on the memory circuit 121 in response to the reset command CMD_RESET. Operation S551 and operation S552 are similar to operation S351 and operation S352 of FIG. 6 or operation S451 and operation S452 of FIG. 7, and thus, additional description will be omitted to avoid redundancy.

In the above embodiments, a configuration of the memory circuit 121 or a configuration in which the refresh operation is performed on the entire device information DINF is described, but the present disclosure is not limited thereto. For example, in the embodiment of FIG. 8B, the memory device 120 may perform the CRC-check operation in units of sub-information of the device information DINF. In this case, the memory device 120 may only perform the CRC-check operation on sub-information whose CRC-check operation fails, in response to the reset command CMD_RESET from the controller 110. That is, as the refresh operation on sub-information, in which an error occurs, from among the plurality of sub-information DINF_s1 to DINF_sn is only performed, the overhead for recovering the error of the device information DINF may be reduced. For example, by solely refreshing the sub-information with errors among the sub-information DINF_s1 to DINF_sn of the device information DINF, the burden of correcting errors in the device information DINF may be lowered, thereby reducing overhead.

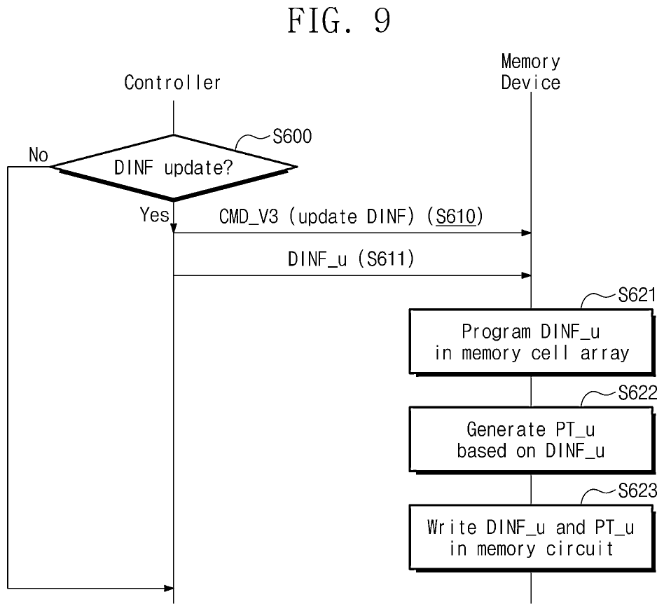

FIG. 9 is a flowchart illustrating an operation of a storage device of FIG. 1. Referring to FIGS. 1, 2, and 9, in operation S600, the controller 110 may determine whether there is a need to update the device information DINF of the memory device 120. For example, the change in a read voltage level may be required depending on an operating environment of the memory device 120. In this case, the update of the device information DINF of the memory device 120 may be required. The above update of the device information DINF is only an example, and the present disclosure is not limited thereto.

When the update of the device information DINF of the memory device 120 is required, in operation S610, the controller 110 may transmit a third command CMD_V3 to the memory device 120. In an embodiment, the third command CMD_V3 may be a universal internal BUS (UIB) write command. In an embodiment, the third command CMD_V3 may be a “SET FEATURE” command for updating the device information DINF. In an embodiment, the third command CMD_V3 may be implemented with a reserved command for a specific operation defined in a memory interface protocol, a vendor command, or a combination of at least two operation commands defined in the memory interface protocol.

In operation S611, the controller 110 may transmit updated device information DINF_u to the memory device 120. In an embodiment, the updated device information DINF_u may be transmitted to the memory device 120 through the second signal lines SIGL2. In an embodiment, the updated device information DINF_u may be transmitted to the memory device 120 in the same manner as the data DATA. For example, the updated device information DINF_u may be transmitted to the memory device 120 through the first signal lines SIGL1.

In operation S621, the memory device 120 may program the updated device information DINF_u in the memory cell array 123. For example, the memory device 120 may program the updated device information DINF_u in a region where the device information DINF is stored. In an embodiment, the memory device 120 may program the updated device information DINF_u in at least one specific memory block or at least one given memory block corresponding to a meta region of the memory cell array 123. In operation S622, the memory device 120 may generate an updated parity PT_u, based on the updated device information DINF_u. In operation S623, the memory device 120 may write the updated device information DINF_u and the updated parity PT_u in the memory circuit 121.

As described above, the device information DINF of the memory device 120 may be updated under the control of the controller 110. In this case, the memory device 120 may generate the updated parity PT_u based on the updated device information DINF_u and may write the updated parity PT_u in the memory circuit 121 together with the updated device information DINF_u. The memory device 120 may perform the CRC-check operation on the memory circuit 121 by using the updated parity PT_u.

In an embodiment, as described with reference to FIG. 8A, the device information DINF may be divided into the plurality of sub-information DINF_s1 to DINF_sn, and the controller 110 may perform the update in units of sub-information. In this case, the memory device 120 may generate an updated parity in units of sub-information and may write the updated parity in the memory circuit 121.

As described above, according to an embodiment of the present disclosure, in response to the first command CMD_V1 from the controller 110, the memory device 120 may perform the CRC-check operation on the device information DINF stored in the memory circuit 121 and may detect an error on the device information DINF. In this case, the error of the device information DINF may come from a soft error occurring in the memory circuit 121. When an error is detected from the device information DINF, the memory device 120 may perform the refresh operation on the memory circuit 121 under the control of the controller 110, and thus, the error of the device information DINF may be cured. Accordingly, prevention of unnecessary refreshing operation of the memory circuit 121 may enhance the performance of the memory device 120.

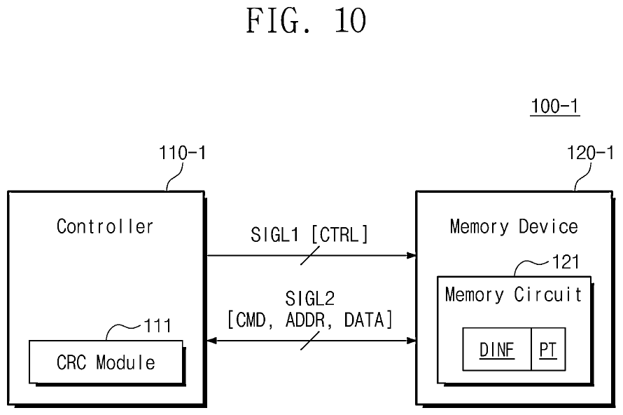

FIG. 10 is a block diagram illustrating a storage device according to an embodiment of the present disclosure. Referring to FIG. 10, a storage device 100-1 may include a controller 110-1 and a memory device 120-1. The controller 110-1 and the memory device 120-1 may communicate with each other through the first signal lines SIGL1 and the second signal lines SIGL2. Operations of the controller 110-1 and the memory device 120-1 are similar to those described with reference to FIG. 1, and thus, additional description will be omitted to avoid redundancy.

In an embodiment, the controller 110-1 may include a CRC module 111. The CRC module 111 may generate the parity PT of the device information DINF stored in the memory circuit 121 of the memory device 120-1. The CRC module 111 may detect an error of the device information DINF stored in the memory circuit 121 of the memory device 120-1, based on the parity PT stored in the memory circuit 121 of the memory device 120-1. When an error is detected from the device information DINF, the controller 110-1 may perform the refresh operation on the memory circuit 121 of the memory device 120-1.

As described above, the controller 110-1 may perform the refresh operation on the memory circuit 121 of the memory device 120-1 by using the CRC module 111. Accordingly, the reliability of the device information DINF may be maintained.

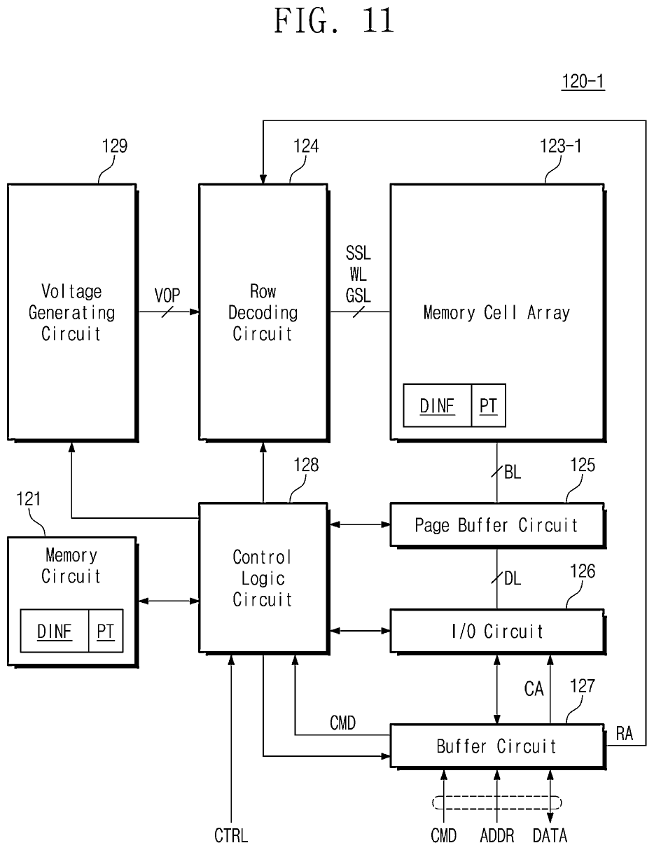

FIG. 11 is a block diagram illustrating a memory device of FIG. 10. Referring to FIGS. 10 and 11, the memory device 120-1 may include the memory circuit 121, a memory cell array 123-1, the row decoding circuit 124, the page buffer circuit 125, the data input/output circuit 126, the buffer circuit 127, the control logic circuit 128, and the voltage generating circuit 129. The row decoding circuit 124, the page buffer circuit 125, the data input/output circuit 126, the buffer circuit 127, the control logic circuit 128, and the voltage generating circuit 129 are similar to those described with reference to FIG. 2, and thus, additional description will be omitted to avoid redundancy.

In an embodiment, the memory cell array 123-1 may store the device information DINF and the parity PT. For example, the device information DINF and the parity PT may be stored in a specific region of the memory cell array 123-1 (e.g., a meta region or a meta block). In the embodiments described with reference to FIGS. 1 to 9, the memory device 120 may include the CRC module 122; however, in the embodiment of FIGS. 10 and 11, the CRC module 111 may be included in the controller 110-1. In this case, the parity PT of the device information DINF may be generated by the controller 110-1, and the device information DINF and the parity PT may be stored in the memory cell array 123-1 together.

In an embodiment, in the initialization operation of the memory device 120-1 or the refresh operation on the memory circuit 121, the memory device 120-1 may write the device information DINF and the parity PT stored in the memory cell array 123-1 in the memory circuit 121.

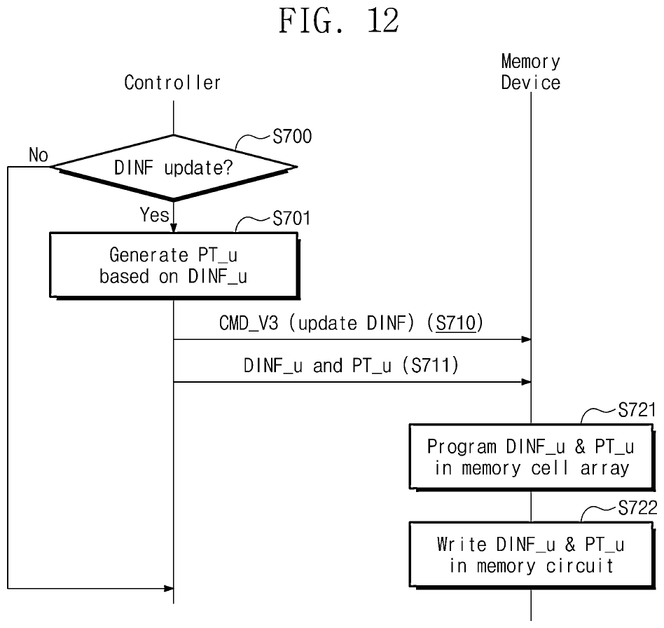

FIG. 12 is a flowchart illustrating an operation of a storage device of FIG. 10. Referring to FIGS. 10, 11, and 12, in operation S700, the controller 110-1 may determine whether there is a need to update the device information DINF of the memory device 120-1. Operation S700 is similar to operation S600 of FIG. 9, and thus, additional description will be omitted to avoid redundancy.

When the update of the device information DINF is required, in operation S701, the controller 110-1 may generate the updated parity PT_u based on the updated device information DINF_u.

In operation S710, the controller 110-1 may transmit the third command CMD_V3 to the memory device 120-1. The third command CMD_V3 may be a command for updating the device information DINF of the memory device 120-1. Operation S710 is similar to operation S610 of FIG. 9, and thus, additional description will be omitted to avoid redundancy.

In operation S711, the controller 110-1 may transmit the updated device information DINF_u and the updated parity PT_u to the memory device 120-1.

In operation S721, in response to the third command CMD_V3, the memory device 120-1 may program the updated device information DINF_u and the updated parity PT_u in the memory cell array 123-1.

In operation S722, the memory device 120-1 may write the updated device information DINF_u and the updated parity PT_u in the memory circuit 121.

As described above, the controller 110-1 may update the device information DINF of the memory device 120-1; in this case, the controller 110-1 may write the updated parity PT_u in the memory device 120-1 and the memory circuit 121 together with the updated device information DINF_u.

In the embodiment of FIG. 12, a configuration of updating the entire device information DINF is described, but the present disclosure is not limited thereto. For example, as described with reference to FIG. 8A, the device information DINF may be divided into the plurality of sub-information DINF_s1 to DINF_sn, and the controller 110-1 may update the device information DINF and the parity PT in units of sub-information and may write the updated sub-information and sub-parity in the memory cell array 123-1 and the memory circuit 121 of the memory device 120-1.

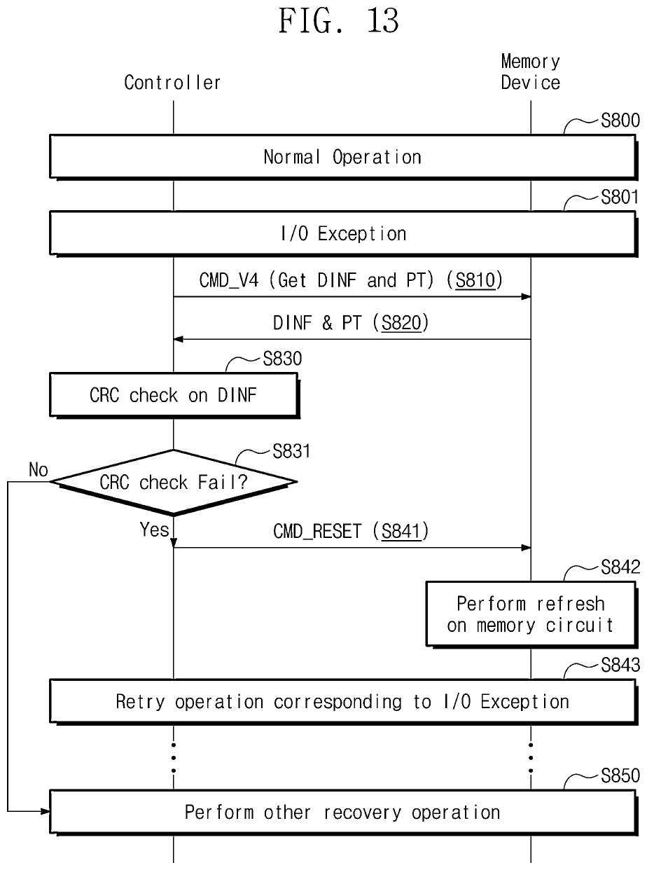

FIG. 13 is a flowchart illustrating an operation of a storage device of FIG. 10. Referring to FIGS. 10, and 13, in operation S800, the controller 110-1 and the memory device 120-1 may perform the normal operation of the NAND flash memory, for example. In operation S801, an input/output exception may occur. Operation S800 and operation S801 are similar to operation S300 and operation S301 of FIG. 6, and thus, additional description will be omitted to avoid redundancy.

When the input/output exception occurs, in operation S810, the controller 110-1 may transmit a fourth command CMD_V4 to the memory device 120-1. For example, the controller 110-1 may transmit the fourth command CMD_V4 to obtain the device information DINF and the parity PT stored in the memory circuit 121 of the memory device 120-1. In an embodiment, the fourth command CMD_V4 may be implemented with a vendor command or reserved command defined to support an operation of reading the device information DINF and the parity PT stored in the memory circuit 121 of the memory device 120-1 or may be implemented with a combination of various operation commands.

In operation S820, the memory device 120-1 may transmit the device information DINF and the parity PT stored in the memory circuit 121 to the controller 110-1 in response to the fourth command CMD_V4.

In operation S830, the controller 110-1 may perform the CRC-check operation on the device information DINF by using the received parity PT.

In operation S831, the memory controller 110-1 may determine whether the CRC-check operation fails. When the CRC-check operation fails (i.e., when an error is included in the device information DINF), the controller 110-1 and the memory device 120-1 may perform operation S841, operation S842, and operation S843. When the CRC-check operation succeeds (i.e., when an error is absent from the device information DINF), the controller 110-1 and the memory device 120-1 may perform operation S850. Operation S841, operation S842, operation S843, and operation S850 are similar to operation S351, operation S352, operation S353, and operation S360 of FIG. 6, and thus, additional description will be omitted to avoid redundancy.

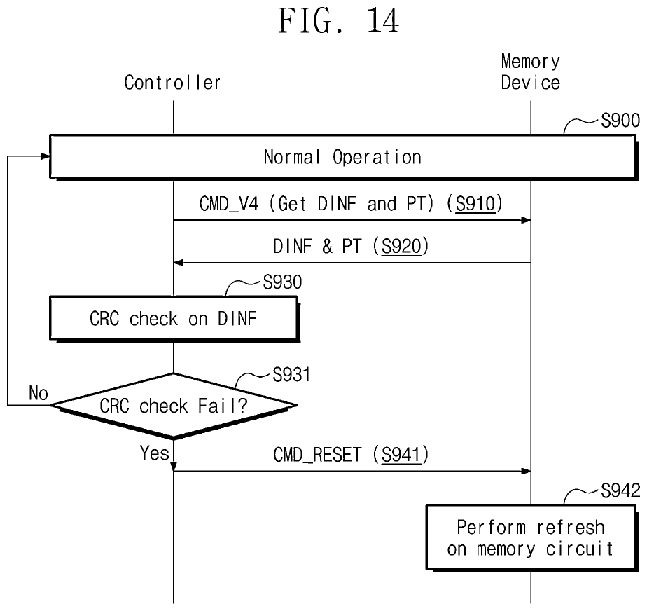

FIG. 14 is a flowchart illustrating an operation of a storage device of FIG. 10. Referring to FIGS. 10 and 14, in operation S900, the controller 110-1 and the memory device 120-1 may perform the normal operation of the NAND flash memory, for example.

In operation S910, the controller 110-1 may transmit the fourth command CMD_V4 to the memory device 120-1. The fourth command CMD_V4 may be a command for obtaining the device information DINF and the parity PT stored in the memory circuit 121 of the memory device 120-1. In an embodiment, the fourth command CMD_V4 may be a “GET FEATURE” command. In an embodiment, the fourth command CMD_V4 may be implemented with a reserved command for a specific operation defined in a memory interface protocol, a vendor command, or a combination of at least two operation commands defined in the memory interface protocol.

The controller 110-1 and the memory device 120-1 may perform operation S920, operation S930, operation S931, operation S941, and operation S942. Operation S930, operation S931, operation S941, and operation S942 are similar to operation S830, operation S831, operation S841, and operation S842 of FIG. 13, and thus, additional description will be omitted to avoid redundancy.

In an embodiment, when the CRC-check operation succeeds (i.e., when an error is absent from the device information DINF), the controller 110-1 and the memory device 120-1 may continue operation S900 (i.e., the normal operation of the NAND flash memory, for example).

In the embodiment of FIG. 14, regardless of the input/output exception of the memory device 120-1, the controller 110-1 may transmit the fourth command CMD_V4 to the memory device 120-1 and may perform the CRC-check operation on the device information DINF stored in the memory circuit 121 of the memory device 120-1. For example, the controller 110-1 may periodically or non-periodically transmit the fourth command CMD_V4 to the memory device 120-1. As an example, during an idle time of the memory device 120-1, the controller 110-1 may transmit the fourth command CMD_V4 to the memory device 120-1. As an example, whenever an operation count or the number of program/erase cycles of the memory device 120-1 reaches a reference value, the controller 110-1 may transmit the fourth command CMD_V4 to the memory device 120-1. In an embodiment, whenever a driving time of the memory device 120-1 reaches a reference time, the controller 110-1 may transmit the fourth command CMD_V4 to the memory device 120-1.

That is, even though the input/output exception does not occur in the memory device 120-1, the controller 110-1 may periodically or non-periodically determine whether an error occurs in the device information DINF stored in the memory circuit 121 of the memory device 120-1. In this case, the reliability of the device information DINF stored in the memory circuit 121 may be improved. Accordingly, prevention of unmercenary refresh operation of the memory circuit 121 may enhance the performance of the memory device 120-1 or the storage device 100.

An embodiment in which the controller 110-1 performs the CRC-check operation on the entire device information DINF of the memory circuit 121 of the memory device 120-1 is described with reference to FIG. 14, but the present disclosure is not limited thereto. For example, as described with reference to FIG. 8B, the device information DINF may be divided into the plurality of sub-information DINF_s1 to DINF_sn, and the controller 110-1 may perform the CRC-check operation on the device information DINF in units of sub-information.

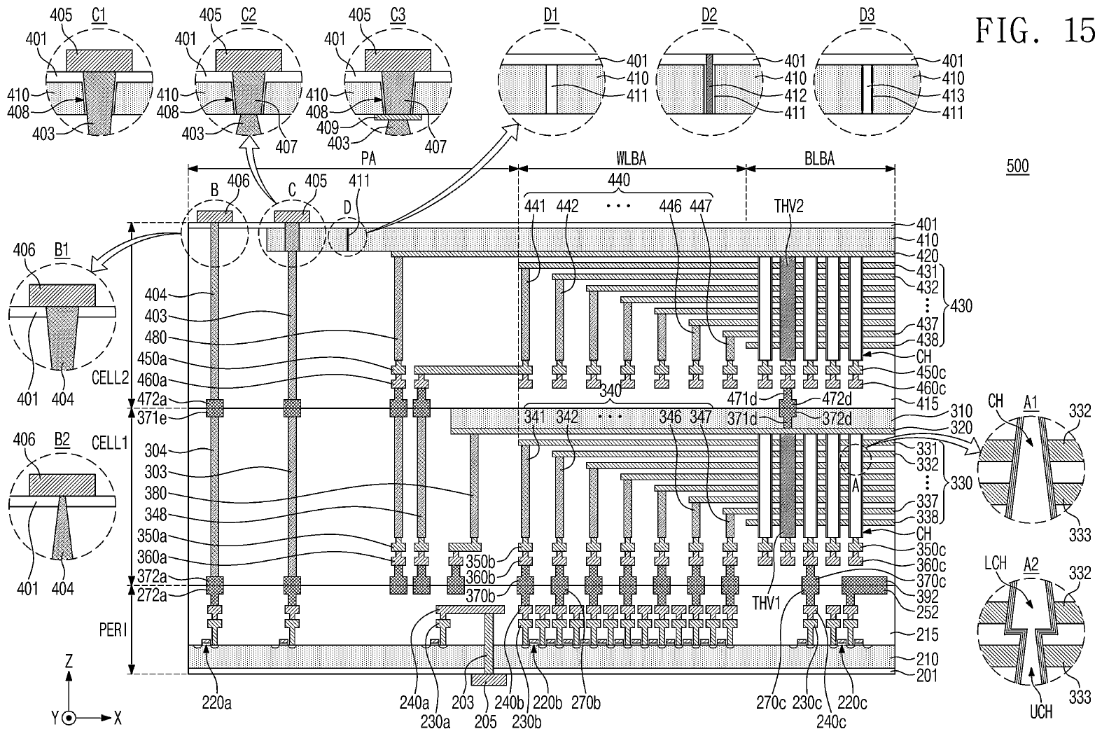

FIG. 15 is a view illustrating a memory device 500 according to an embodiment of the present disclosure.

Referring to FIG. 15, the memory device 500 may have a chip-to-chip (C2C) structure. In the C2C structure, after fabricating at least one upper chip including a cell region CELL and at least one lower chip including a peripheral circuit region PERI, the upper chip and the lower chip may be bonded to each other by a bonding method. The bonding method may refer to a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. In an embodiment, the bonding metal patterns may be formed of aluminum (Al) or tungsten (W).

The memory device 500 may include at least one or more upper chips including a cell region. As illustrated in FIG. 15, the memory device 500 may be implemented to include two upper chips. However, the present disclosure is not limited thereto. For example, the number of upper chips is not limited thereto. In the case where the memory device 500 is implemented to include two upper chips, the memory device 500 may be manufactured by separately manufacturing a first upper chip including a first cell region CELL1, a second upper chip including a second cell region CELL2, and a lower chip including a peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. That is, in FIG. 15, an upper portion of the lower chip refers to an upper portion defined based on a +Z-axis direction, and the upper portions of the first and second upper chips refer to upper portions defined based on a −Z-axis direction. However, this is illustrative, and only one of the first upper chip and the second upper chip may be turned over and connected by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal lines connecting the plurality of circuit elements 220a, 220b, and 220c with each other may be provided in the interlayer insulating layer 215. For example, the plurality of metal lines may include first metal lines 230a, 230b, and 230c connected with the plurality of circuit elements 220a, 220b, and 220c, respectively, and second metal lines 240a, 240b, and 240c formed on the first metal lines 230a, 230b, and 230c. The plurality of metal lines may be formed of at least one of various conductive materials. For example, the first metal lines 230a, 230b, and 230c may be formed of tungsten having a relatively high electrical resistivity, and the second metal lines 240a, 240b, and 240c may be formed of copper having a relatively low electrical resistivity.

In this specification, only the first metal lines 230a, 230b, and 230c and the second metal lines 240a, 240b, and 240c are illustrated and described. However, without being limited thereto, one or more additional metal lines may be further formed on the second metal lines 240a, 240b, and 240c. In this case, the second metal lines 240a, 240b, and 240c may be formed of aluminum. At least some of the additional metal lines formed on the second metal lines 240a, 240b, and 240c may be formed of copper having a lower electrical resistivity than the aluminum of the second metal lines 240a, 240b, and 240c.

The interlayer insulating layer 115 may be disposed on the first substrate 210 and may include or may be formed of an insulating material, such as silicon oxide and silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (the Z-axis direction) perpendicular to an upper surface of the second substrate 310. String selection lines and a ground selection line may be disposed on and under the word lines 330, respectively. For example, the plurality of word lines 330 may be disposed between the string selection lines and the ground selection line. Likewise, the second cell region CELL2 may include a third substrate 410 and a common source line 420, and a plurality of word lines 430 (431 to 438) may be stacked in a direction (the Z-axis direction) perpendicular to an upper surface of the third substrate 410. The second substrate 310 and the third substrate 410 may be formed of various materials and may be, for example, silicon substrates, silicon-germanium substrates, germanium substrates, or substrates having mono-crystalline epitaxial layers grown on mono-crystalline silicon substrates. A plurality of channel structures CH may be formed in the first and second cell regions CELL1 and CELL2.

In an embodiment, as illustrated in an embodiment A1, the channel structure CH may be provided in the bit line bonding region BLBA and may extend in the direction perpendicular to the upper surface of the second substrate 310 to penetrate the word lines 330, the string selection lines, and the ground selection line. The channel structure CH may include a data storage layer, a channel layer, and a buried insulating layer. The channel layer may be electrically connected to a first metal line 350c and a second metal line 360c in the bit line bonding region BLBA. For example, the second metal line 360c may be a bit line and may be connected to the channel structure CH through the first metal line 350c. The bit line 360c may extend in a first direction (a Y-axis direction) parallel to the upper surface of the second substrate 310.

In an embodiment, as illustrated in an embodiment A2, the channel structure CH may include a lower channel LCH and an upper channel UCH connected with each other. For example, the channel structure CH may be formed through a process of forming the lower channel LCH and a process of forming the upper channel UCH. The lower channel LCH may extend in the direction perpendicular to the upper surface of the second substrate 310 and may penetrate the common source line 320 and the lower word lines 331 and 332. The lower channel LCH may include a data storage layer, a channel layer, and a buried insulating layer and may be connected to the upper channel UCH. The upper channel UCH may penetrate the upper word lines 333 to 338. The upper channel UCH may include a data storage layer, a channel layer, and a buried insulating layer, and the channel layer of the upper channel UCH may be electrically connected to the first metal line 350c and the second metal line 360c. As the length of a channel is increased, it may be difficult to form a channel having a constant width due to process reasons. The memory device 500 according to an embodiment of the present disclosure may include a channel having improved width uniformity through the lower channel LCH and the upper channel UCH formed by sequential processes.

In the case in which the channel structure CH includes the lower channel LCH and the upper channel UCH as illustrated in an embodiment A2, a word line located near the boundary between the lower channel LCH and the upper channel UCH may be a dummy word line. For example, the lower word line 332 and the upper word line 333 that form the boundary between the lower channel LCH and the upper channel UCH may be dummy word lines. In this case, data may not be stored in memory cells connected to the dummy word lines. In an embodiment, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in the embodiment A2 that the number of lower word lines 331 and 332 penetrated by the lower channel LCH is smaller than the number of upper word lines 333 to 338 penetrated by the upper channel UCH. However, this is illustrative, and the present disclosure is not limited thereto. In an embodiment, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 15, the first through-electrode THV1 may penetrate the common source line 320 and the plurality of word lines 330. However, this is illustrative, and the first through-electrode THV1 may additionally penetrate the second substrate 310. The first through-electrode THV1 may include or may be formed of a conductive material. In an embodiment, the first through-electrode THV1 may include or may be formed of a conductive material surrounded by an insulating material. The second through-electrode THV2 may have the same shape and structure as the first through-electrode THV1.

In an embodiment, the first through-electrode THV1 and the second through-electrode THV2 may be electrically connected through a first through-metal pattern 372d and a second through-metal pattern 472d. The first through-metal pattern 372d may be formed on a lower side of the first upper chip including the first cell region CELL1, and the second through-metal pattern 472d may be formed on an upper side of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected by a bonding method.

Furthermore, in the bit line bonding region BLBA, an upper metal pattern 252 may be formed at the uppermost metal layer of the peripheral circuit region PERI, and an upper metal pattern 392 having the same shape as the upper metal pattern 252 may be formed at the uppermost metal layer of the first cell region CELL1. The upper metal pattern 392 of the first cell region CELL1 and the upper metal pattern 252 of the peripheral circuit region PERI may be electrically connected with each other by a bonding method. In the bit line bonding region BLBA, the bit line 360c may be electrically connected to a page buffer included in the peripheral circuit region PERI. For example, some of the circuit elements 220c of the peripheral circuit region PERI may provide a page buffer, and the bit line 360c may be electrically connected to the circuit elements 220c providing the page buffer through an upper bonding metal 370c of the first cell region CELL1 and an upper bonding metal 270c of the peripheral circuit region PERI.

Referring to FIG. 15, in the word line bonding region WLBA, the word lines 330 of the first cell region CELL1 may extend in a second direction (an X-axis direction) parallel to the upper surface of the second substrate 310 and may be connected to a plurality of cell contact plugs 341 to 347, which are collectively referred to as 340. A first metal line 350b and a second metal line 360b may be sequentially connected to upper portions of the cell contact plugs 340 connected to the word lines 330. In the word line bonding region WLBA, the cell contact plugs 340 may be connected to the peripheral circuit region PERI through an upper bonding metal 370b of the first cell region CELL1 and an upper bonding metal 270b of the peripheral circuit region PERI.

The cell contact plugs 340 may be electrically connected to a row decoder included in the peripheral circuit region PERI. For example, some of the circuit elements 220b of the peripheral circuit region PERI may provide a row decoder, and the cell contact plugs 340 may be electrically connected to the circuit elements 220b providing the row decoder through the upper bonding metal 370b of the first cell region CELL1 and the upper bonding metal 270b of the peripheral circuit region PERI. In an embodiment, an operating voltage of the circuit elements 220b that provide the row decoder may differ from an operating voltage of the circuit elements 220c that provide the page buffer. For example, the operating voltage of the circuit elements 220c that provide the page buffer may be greater than the operating voltage of the circuit elements 220b that provide the row decoder.

Likewise, in the word line bonding region WLBA, the word lines 430 of the second cell region CELL2 may extend in the second direction (the X-axis direction) parallel to the upper surface of the third substrate 410 and may be connected to a plurality of cell contact plugs 441 to 447, which are collectively referred to as 440. The cell contact plugs 440 may be connected to the peripheral circuit region PERI through an upper metal pattern of the second cell region CELL2, a lower metal pattern and an upper metal pattern of the first cell region CELL1, and a cell contact plug 348.

In the word line bonding region WLBA, the upper bonding metal 370b may be formed in the first cell region CELL1, and the upper bonding metal 270b may be formed in the peripheral circuit region PERT. The upper bonding metal 370b of the first cell region CELL1 and the upper bonding metal 270b of the peripheral circuit region PERI may be electrically connected with each other by a bonding method. The upper bonding metal 370b and the upper bonding metal 270b may be formed of aluminum, copper, or tungsten.

In the external pad bonding region PA, a lower metal pattern 371e may be formed on a lower portion of the first cell region CELL1, and an upper metal pattern 472a may be formed on an upper portion of the second cell region CELL2. The lower metal pattern 371e of the first cell region CELL1 and the upper metal pattern 472a of the second cell region CELL2 may be connected with each other by a bonding method in the external pad bonding region PA. Likewise, an upper metal pattern 372a may be formed on an upper portion of the first cell region CELL1, and an upper metal pattern 272a may be formed on an upper portion of the peripheral circuit region PERI. The upper metal pattern 372a of the first cell region CELL1 and the upper metal pattern 272a of the peripheral circuit region PERI may be connected with each other by a bonding method.

Common source line contact plugs 380 and 480 may be disposed in the external pad bonding region PA. The common source line contact plugs 380 and 480 may be formed of a conductive material, such as metal, a metal compound, and doped poly-silicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on an upper portion of the common source line contact plug 380 of the first cell region CELL1, and a first metal line 450a and a second metal line 460a may be sequentially stacked on an upper portion of the common source line contact plug 480 of the second cell region CELL2.

Input/output pads 205, 405, and 406 may be disposed in the external pad bonding region PA. Referring to FIG. 15, a lower insulating layer 201 may cover a lower surface of the first substrate 210, and the first input/output pad 205 may be formed on the lower insulating layer 201. The first input/output pad 205 may be connected to at least one of the plurality of circuit elements 220a disposed in the peripheral circuit region PERI through a first input/output contact plug 203 and may be separated from the first substrate 210 by the lower insulating layer 201. In addition, a side insulating layer may be disposed in a space between the first input/output contact plug 203 and the first substrate 210 and may electrically isolate the first input/output contact plug 203 from the first substrate 210.

An upper insulating layer 401 may be formed on the third substrate 410 to cover the upper surface of the third substrate 410. The second input/output pad 405 and/or the third input/output pad 406 may be disposed on the upper insulating layer 401. The second input/output pad 405 may be connected to at least one of the plurality of circuit elements 220a disposed in the peripheral circuit region PERI through second input/output contact plugs 403 and 303, and the third input/output pad 406 may be connected to at least one of the plurality of circuit elements 220a disposed in the peripheral circuit region PERI through third input/output contact plugs 404 and 304.

In an embodiment, the third substrate 410 may not be disposed in the regions where the input/output contact plugs are disposed. For example, as illustrated in region B, the third input/output contact plug 404 may be separated from the third substrate 410 in a direction parallel to the upper surface of the third substrate 410, may penetrate an interlayer insulating layer 415 of the second cell region CELL2, and may be connected to the third input/output pad 406. In this case, the third input/output contact plug 404 may be formed through various processes.

For example, as illustrated in an embodiment B1, the third input/output contact plug 404 may extend in the third direction (the Z-axis direction) and may have an increasing diameter toward the upper insulating layer 401. That is, while the channel structure CH described with reference to the embodiment A1 has a decreasing diameter toward the upper insulating layer 401, the third input/output contact plug 404 may have an increasing diameter toward the upper insulating layer 401. For example, the third input/output contact plug 404 may be formed after the second cell region CELL2 and the first cell region CELL1 are coupled by a bonding method.

For example, as illustrated in an embodiment B2, the third input/output contact plug 404 may extend in the third direction (the Z-axis direction) and may have a decreasing diameter toward the upper insulating layer 401. That is, likewise the channel structure CH, the third input/output contact plug 404 may have a decreasing diameter toward the upper insulating layer 401. For example, the third input/output contact plug 404 may be formed together with the cell contact plugs 440 before the second cell region CELL2 and the first cell region CELL1 are coupled by a bonding method.

In an embodiment, an input/output contact plug may be disposed to overlap the third substrate 410. For example, as illustrated in region C, the second input/output contact plug 403 may pass through the interlayer insulating layer 415 of the second cell region CELL2 and the third substrate 410 in the third direction (the Z-axis direction) and may be electrically connected to the second input/output pad 405. In this case, a connection structure of the second input/output contact plug 403 and the second input/output pad 405 may be implemented in various ways.

For example, as illustrated in an embodiment C1, an opening 408 may be formed through the third substrate 410, and the second input/output contact plug 403 may be directly connected to the second input/output pad 405 through the opening 408 formed in the third substrate 410. In this case, as illustrated in the embodiment C1, the second input/output contact plug 403 may have an increasing diameter toward the second input/output pad 405. However, this is illustrative, and the second input/output contact plug 403 may have a decreasing diameter toward the second input/output pad 405.

For example, as illustrated in an embodiment C2, the opening 408 may be formed through the third substrate 410, and a contact 407 may be formed in the opening 408. One end portion of the contact 407 may be connected to the second input/output pad 405, and an opposite end portion of the contact 407 may be connected to the second input/output contact plug 403. Accordingly, the second input/output contact plug 403 may be electrically connected to the second input/output pad 405 through the contact 407 in the opening 408. In this case, as illustrated in the embodiment C2, the contact 407 may have an increasing diameter toward the second input/output pad 405, and the second input/output contact plug 403 may have a decreasing diameter toward the second input/output pad 405. For example, the third input/output contact plug 403 may be formed together with the cell contact plugs 440 before the second cell region CELL2 and the first cell region CELL1 are coupled with each other by a bonding method, and the contact 407 may be formed after the second cell region CELL2 and the first cell region CELL1 are coupled with each other by the bonding method.

For example, as illustrated in an embodiment C3, a stopper 409 may be additionally formed on an upper surface of the opening 408 of the third substrate 410. The stopper 409 may be a metal line formed on the same layer as the common source line 420. However, this is illustrative, and the stopper 409 may be a metal line formed on the same layer as at least one of the word lines 430. The second input/output contact plug 403 may be electrically connected to the second input/output pad 405 through the contact 407 and the stopper 409.

Meanwhile, similarly to the second and third input/output contact plugs 403 and 404 of the second cell region CELL2, the second and third input/output contact plugs 303 and 304 of the first cell region CELL1 may have a decreasing diameter toward the lower metal pattern 371e, or may have an increasing diameter toward the lower metal pattern 371e.

Meanwhile, in an embodiment, a slit 411 may be formed in the third substrate 410. For example, the slit 411 may be formed at any position in the external pad bonding region PA. For example, as illustrated in region D, the slit 411 may be located between the second input/output pad 405 and the cell contact plugs 440 when viewed in a plan view. However, this is illustrative, and the slit 411 may be formed such that the second input/output pad 405 is located between the slit 411 and the cell contact plugs 440 when viewed in a plan view.

For example, as illustrated in an embodiment D1, the slit 411 may be formed through the third substrate 410. For example, the slit 411 may be used to prevent the third substrate 410 from being finely cracked when the opening 408 is formed. However, this is illustrative, and the slit 411 may be formed to have a depth ranging from about 60% to about 70% of the thickness of the third substrate 410.

For example, as illustrated in an embodiment D2, a conductive material 412 may be formed in the slit 411. For example, the conductive material 412 may serve to discharge a leakage current generated while circuit elements in the external pad bonding region PA are driven. In this case, the conductive material 412 may be connected to an external ground line.

For example, as illustrated in an embodiment D3, an insulating material 413 may be formed in the slit 411. For example, the insulating material 413 may be formed to electrically isolate the second input/output pad 405 and the second input/output contact plug 403 disposed in the external pad bonding region PA from the word line bonding region WLBA. An influence of a voltage provided through the second input/output pad 405 on a metal layer disposed on the third substrate 410 in the word line bonding region WLBA may be reduced by forming the insulating material 413 in the slit 411.

Meanwhile, in some embodiments, the first to third input/output pads 205, 405, and 406 may be selectively formed. For example, the memory device 500 may be implemented to include only the first input/output pad 205 disposed on the first substrate 210, only the second input/output pad 405 disposed on the third substrate 410, or only the third input/output pad 406 disposed on the upper insulating layer 401.

In some embodiments, at least one of the second substrate 310 of the first cell region CELL1 and the third substrate 410 of the second cell region CELL2 may serve as a sacrificial substrate and may be completely or partially removed before or after a bonding process. An additional layer may be stacked after the removal of the substrate. For example, the second substrate 310 of the first cell region CELL1 may be removed before or after the peripheral circuit region PERI and the first cell region CELL1 are bonded with each other, and an insulating layer for covering an upper surface of the common source line 320 or a conductive layer for connection may be formed. Similarly, the third substrate 410 of the second cell region CELL2 may be removed before or after the first cell region CELL1 and the second cell region CELL2 are bonded with each other, and the upper insulating layer 401 for covering an upper surface of the common source line 420 or a conductive layer for connection may be formed.

In an embodiment, the memory circuit 121 or the CRC module 122 according to embodiments of the present disclosure may be formed in the peripheral circuit region PERI of the memory device 500 of FIG. 15, and the memory device 500 may operate based on the operation method described with reference to FIGS. 1 to 14.

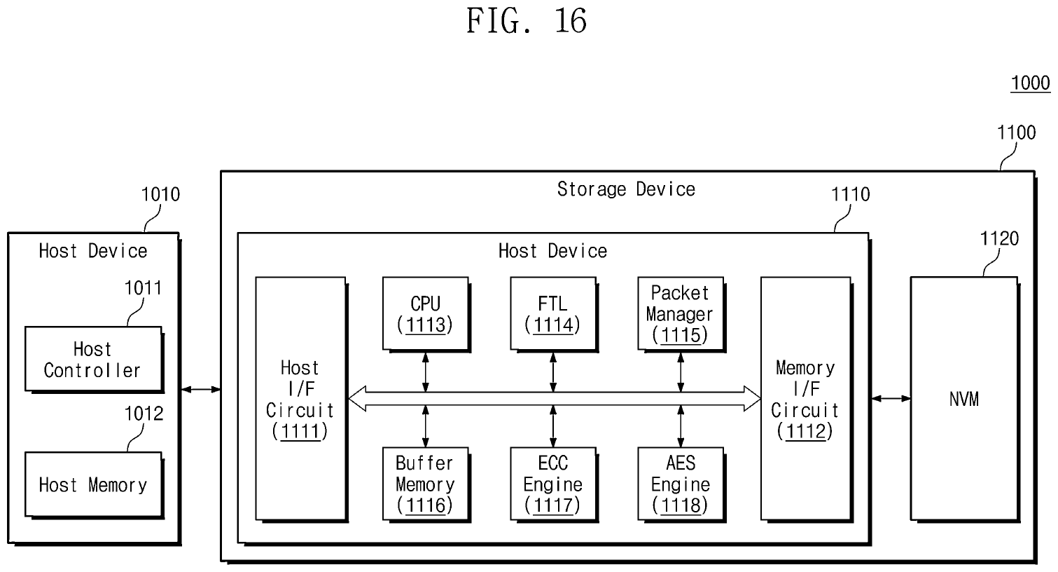

FIG. 16 is a block diagram of a host storage system according to an example embodiment.

The host storage system 1000 may include a host 1010 and a storage device 1100. The storage device 1100 may further include a storage controller 1110 and an NVM 1120. According to an example embodiment, the host 1010 may include a host controller 1011 and a host memory 1012. The host memory 1012 may serve as a buffer memory configured to temporarily store data to be transmitted to the storage device 1100 or data received from the storage device 1100.

The storage device 1100 may include storage media configured to store data in response to requests from the host 1010. In an embodiment, the storage device 1100 may include at least one of an SSD, an embedded memory, and a removable external memory. When the storage device 1100 is an SSD, the storage device 1100 may be a device that conforms to an NVMe standard. When the storage device 1100 is an embedded memory or an external memory, the storage device 1100 may be a device that conforms to a UFS standard or an eMMC standard. Each of the host 1010 and the storage device 1100 may generate a packet according to an adopted standard protocol and transmit the packet.

When the NVM 1120 of the storage device 1100 includes a flash memory, the flash memory may include a two-dimensional (2D) NAND memory array or a three dimensional (3D) NAND memory array, which may be referred to as a VNAND memory array. In an embodiment, the storage device 1100 may include various other kinds of NVMs. For example, the storage device 1100 may include magnetic RAM (MRAM), spin-transfer torque MRAM, conductive bridging RAM (CBRAM), ferroelectric RAM (FRAM), PRAM, RRAM, and various other kinds of memories.

According to an embodiment, the host controller 1011 and the host memory 1012 may be implemented as separate semiconductor chips. In an embodiment, the host controller 1011 and the host memory 1012 may be integrated in the same semiconductor chip. In an embodiment, the host controller 1011 may be any one of a plurality of modules included in an application processor (AP). The AP may be implemented as a System on Chip (SoC). Further, the host memory 1012 may be an embedded memory included in the AP or an NVM or memory module located outside the AP.

The host controller 1011 may manage an operation of storing data (e.g., write data) of a buffer region of the host memory 1012 in the NVM 1120 or an operation of storing data (e.g., read data) of the NVM 1120 in the buffer region.

The storage controller 1110 may include a host interface 1111, a memory interface 112, and a CPU 113. The storage controller 1110 may further include a flash translation layer (FTL) 114, a packet manager 115, a buffer memory 116, an error correction code (ECC) engine 117, and an advanced encryption standard (AES) engine 118. The storage controller 1110 may further include a working memory (not shown) in which the FTL 114 is loaded. The CPU 113 may execute the FTL 114 to control data write and read operations on the NVM 1120.

The host interface 1111 may transmit and receive packets to and from the host 1010. A packet transmitted from the host 1010 to the host interface 1111 may include a command or data to be written to the NVM 1120. A packet transmitted from the host interface 1111 to the host 1010 may include a response to the command or data read from the NVM 1120. The memory interface 1112 may transmit data to be written to the NVM 1120 to the NVM 1120 or receive data read from the NVM 1120. The memory interface 1112 may be configured to comply with a standard memory interface protocol, such as Toggle and ONFI.

The FTL 1114 may perform various functions, such as an address mapping operation, a wear-leveling operation, and a garbage collection operation. The address mapping operation may be an operation of converting a logical address received from the host 1010 into a physical address of the NVM 1120. The wear-leveling operation may be a technique for preventing excessive deterioration of a specific block by allowing blocks of the NVM 1120 to be uniformly used. In an embodiment, the wear-leveling operation may be implemented using a firmware that balances erase counts of physical blocks. The garbage collection operation may be a technique for ensuring usable capacity in the NVM 1120 by erasing an existing block after copying valid data of the existing block to a new block.

The packet manager 1115 may generate a packet according to a protocol of an interface, which is compatible with the host 1010, or parse various types of information from the packet received from the host 1010. In addition, the buffer memory 1116 may temporarily store data to be written to the NVM 1120 or data to be read from the NVM 1120. Although the buffer memory 116 may be a component included in the storage controllers 1110, the buffer memory 116 may be outside the storage controller 1110.

The ECC engine 1117 may perform error detection and correction operations on data read from the NVM 1120. More specifically, the ECC engine 1117 may generate parity bits for write data to be written to the NVM 1120, and the generated parity bits may be stored in the NVM 1120 together with write data. During the reading of data from the NVM 1120, the ECC engine 1117 may correct an error in the read data by using the parity bits read from the NVM 1120 along with the read data, and output error-corrected read data.

The AES engine 1118 may perform at least one of an encryption operation and a decryption operation on data input to the storage controllers 1110 by using a symmetric-key algorithm.

In an embodiment, the storage controller 1110 of FIG. 16 may be the controller 110 or 110-1 described with reference to FIGS. 1 to 14, and the nonvolatile memory (NVM) 1120 may be the memory devices 120, 120-1, or 500 described with reference to FIGS. 1 to 15. The storage device 1100, the storage controller 1110, and the nonvolatile memory (NVM) 1120 may operate based on the operation method described with reference to FIGS. 1 to 15.

According to the present disclosure, an operation method of a memory device with improved reliability and improved performance, an operation method of a controller configured to control the memory device, and an operation method of a storage device including the same are provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method of operating a memory device including a memory cell array and a memory circuit, the method comprising:
receiving a first command from a controller;
determining, in response to the first command, whether first device information stored in the memory circuit has an error;
receiving, in response to the determining that the first device information has the error, a reset command from the controller; and
performing a refresh operation on the memory circuit in response to the reset command,
wherein the first device information includes information about an operation parameter and an operating frequency of the memory device.

2. The method of claim 1, further comprising:
storing the first device information in a plurality of latch circuits of the memory circuit by programming a plurality of programmable electrical fuses of the memory circuit.

3. The method of claim 1,
wherein the first command is a reserved command defined in a memory interface protocol between the controller and the memory device, a vendor command, or a combination of at least two operation commands defined in the memory interface protocol.

4. The method of claim 1,
wherein the determining of whether the first device information has the error includes:
performing a CRC-check operation on the first device information based on a first parity stored in the memory circuit;
writing a result of the CRC-check operation in a status register;
receiving a status read command from the controller; and
transmitting a value of the status register to the controller in response to the status read command.

5. The method of claim 1,
wherein the performing of the refresh operation on the memory circuit in response to the reset command includes:
reading second device information stored in the memory cell array;
generating a second parity of the second device information; and
writing the second parity and the second device information in the memory circuit as the first device information and a first parity related to the first device information.

6. The method of claim 1, further comprising:
receiving the first command from the controller which detects an input/output exception occurring during an operation of the memory device.

7. The method of claim 1,
wherein the first command is received from the controller which detects that the memory device is in an idle time period.

8. The method of claim 1, further comprising:
receiving a second command and an update device information from the controller; and
performing, in response to the second command, an operation of programming the updated device information in the memory cell array, generating an updated parity of the updated device information, and writing the updated device information and the updated parity in the memory circuit as the first device information and a first parity stored in the memory circuit.

9. The method of claim 1, further comprising:
performing an initialization operation on the memory device,
wherein the performing of the initialization operation includes:
generating a second parity based on second device information stored in the memory cell array; and
writing the second device information and the second parity in the memory circuit as the first device information and a first parity related to the first device information.

10. A method of operating a controller to control a memory device, the method comprising:
transmitting a first command to the memory device;
transmitting a status read command to the memory device;
receiving status information from the memory device;
determining whether an error is present in device information stored in a memory circuit included in the memory device based on the status information; and
transmitting, in response to determining that the error is present in the device information, a reset command for refreshing the memory circuit to the memory device,
wherein the device information includes information about an operation parameter and an operating frequency of the memory device.

11. The method of claim 10,
wherein the first command is a reserved command defined in a memory interface protocol between the controller and the memory device, a vendor command, or a combination of at least two operation commands defined in the memory interface protocol.

12. The method of claim 10,
wherein the status information includes information about a cyclic redundancy check (CRC)-check result of the device information stored in the memory circuit.

13. The method of claim 10, further comprising:
detecting whether an input/output exception occurs in an operation of the memory device,
wherein the transmitting of the first command to the memory device is performed in response to detecting that the input/output exception occurs in the memory device.

14. The method of claim 13, further comprising:
performing, in response to the detecting of the input/output exception and determining that the error is absent from the device information, a recovery operation on the memory device.

15. The method of claim 10, further comprising:
detecting whether the memory device is in an idle time period,
wherein the transmitting of the first command is performed in response to detecting that the memory device is in the idle time period.

16. The method of claim 10, further comprising:
detecting whether a driving time of the memory device reaches a reference time,
wherein the transmitting of the first command to the memory device is performed in response to detecting that the driving time of the memory device reaches the reference time.

17. An method of operating a storage device which includes a memory device and a controller, the method comprising:
transmitting, by the controller, a first command to the memory device;
performing, by the memory device, a cyclic redundancy check (CRC)-check operation on device information stored in a memory circuit of the memory device in response to the first command;
receiving, by the controller, a result of the CRC-check operation from the memory device;
transmitting, by the controller, a reset command to the memory device in response to the result of the CRC-check operation indicating that an error is present in the device information; and
performing, by the memory device, a refresh operation on the memory device in response to the reset command,
wherein the device information includes information about an operation parameter and an operating frequency of the memory device.

18. The method of claim 17,
wherein the first command is a reserved command defined in a memory interface protocol between the controller and the memory device, a vendor command, or a combination of at least two operation commands defined in the memory interface protocol.

19. The method of claim 17, further comprising:
detecting, by the controller, an input/output exception of the memory device,
wherein the transmitting, by the controller, the first command to the memory device is performed in response to the input/output exception of the memory device being detected.

20. The method of claim 17, further comprising:
detecting, by the controller, whether the memory device is in an idle time period,
wherein the transmitting, by the controller, the first command to the memory device is performed in response to detecting that the memory device is in the idle time period of the memory device.
